(19) United States
(12) Patent Application Publication
(10) Pub. No.: US 2006/0097760 A1
(43) Pub. Date: May 11, 2006

(54) Differential signal generating circuit, differential signal transmitting circuit and differential signal transceiver system

(75) Inventor: Chikahiro Hori, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ku (JP)

(21) Appl. No.: 11/258,024

(22) Filed: Oct. 26, 2005

(30) Foreign Application Priority Data
Oct. 28, 2004 (JP) 2004-314090

(51) Int. Cl. H03B 1/00

(52) U.S. Cl. 327/108

(57) ABSTRACT

A differential signal generating circuit has first and second transistors connected in series between a first node and a second node, third and fourth transistors connected in series between the first node and the second node, a first differential output terminal connected to a connection path between the first transistor and the second transistor, a second differential output terminal connected to a connection path between the third transistor and the fourth transistor, and a gate signal generating circuit which generates a first gate signal applied to gate terminals of the first and fourth transistors and a second gate signal applied to gate terminals of the second and third transistors, a timing when a logic of the first gate signal changes being different from a timing when a logic of the second gate signal changes.

### CROSS REFERENCE TO RELATED APPLICATIONS

This application claims benefit of priority under 35USC§119 to Japanese Patent Application No. 2004-314090, filed on Oct. 28, 2004, the entire contents of which are incorporated by reference herein.

### BACKGROUND OF THE INVENTION

There has already been proposed LVDS (Low Voltage Differential Signaling), which use a pair of signal lines to transmit low-voltage differential logic signals. In the LVDS, differential signals are transmitted from a transmitting terminal, and the two signal lines are terminated each other by a resistor at a receiving terminal. Binary data of “0” or “1” is generated and transmitted by changing the directions of the currents of the differential signals. At the receiving terminal, a differential amplifier determines a signal value by sensing a higher voltage side of the resistor.

One of the advantages of LVDS is reduction of electromagnetic emission. This is because the current flows in opposite directions through the pair wires for transmitting the signals, and the binary data “0” and “1” are different only in current direction and are equal in current amount. In addition, voltages caused by the resistor at the end of the wires do not change, although higher side of the signal lines changes depending on the signal values “0” or “1”. This also leads to a lower amount of electromagnetic emission.

However, the amount of electromagnetic emission is reduced only when the differential signals on the pair wires are switched substantially ideally. Actually, on switching the differential signals, there is a possibility that voltages of the signals are changed unequally or the directions of the currents flowing through the wires not change smoothly. They are mainly caused by a difference of ON/OFF timing in a plurality of transistors for generating the differential signals.

### SUMMARY OF THE INVENTION

A differential signal generating circuit according to one embodiment of the present invention, comprising:

first and second transistors connected in series between a first node and a second node;

third and fourth transistors connected in series between the first node and the second node;

a first differential output terminal connected to a connection path between the first transistor and the second transistor;

a second differential output terminal connected to a connection path between the third transistor and the fourth transistor; and

a gate signal generating circuit which generates a first gate signal applied to gate terminals of the first and fourth transistors and a second gate signal applied to gate terminals of the second and third transistors, a timing when a logic of the first gate signal changes being different from a timing when a logic of the second gate signal changes.

A differential signal transmitting circuit according to one embodiment of the present invention, comprising;

a differential signal generating circuit which outputs differential signals from a first differential output terminal and a second differential output terminal;

a differential transmission path at one end of which the first and second differential output terminals are connected, which transmits the differential signal; and

an impedance element connected to the differential signals at the other end of the differential transmission path,

wherein the differential signal generating circuit includes:

first and second transistors connected in series between a first node and a second node;

third and fourth transistors connected in series between the first node and the second node; and

a gate signal generating circuit which generates a first gate signal applied to gate terminals of the first and fourth transistors and a second gate signal applied to gate terminals of the second and third transistors, a timing when a logic of the first gate signal changes being different from a timing when a logic of the second gate signal changes,

said first differential output terminal being connected to a connection path of the first and second transistors; and

said second differential output terminal being connected to a connection path of the third and fourth transistors.

A differential signal transceiver system according to one embodiment of the present invention, comprising:

a differential signal generating circuit which outputs differential signals from first and second differential output terminals;

a differential transmission path at one end of which the first and second differential output terminals are connected to transmit the differential signal;

a receiving circuit connected at the other end of the differential transmission path, which receives the differential signals; and

an impedance element connected between the differential signals at the other end of the differential transmission path,

wherein the differential signal generating circuit includes:

first and second transistors connected in series between a first node and a second node;

third and fourth transistors connected in series between the first node and the second node; and

a gate signal generating circuit which generates a first gate signal applied to gate terminals of the first and fourth transistors and a second gate signal applied to gate terminals of the second and third transistors, a timing when a logic of the first gate signal changes being different from a timing when a logic of the second gate signal changes,

said first differential output terminal being connected to a connection path of the first and second transistors; and

said second differential output terminal being connected o a connection path of the third and fourth transistors.

### BRIEF DESCRIPTION OF THE DRAWINGS

FIG. 1 is a circuit diagram showing an example of a differential signal generating circuit that generates differential signals;

FIG. 2 shows waveforms of signals A and B according to the conventional circuit;

FIG. 3 shows waveform of the voltage of differential output terminals around the time when the signals A and B switch the logics thereof according to the conventional circuit;

FIG. 4 is a circuit diagram showing a gate signal generating circuit according to an embodiment, in which the voltage drop shown in FIG. 3 is eliminated;

FIG. 5 shows waveforms of the signals A and B generated by the circuit shown in FIG. 4;

FIG. 6 is a circuit diagram showing a gate signal generating circuit, which is a variation of the circuit shown in FIG. 4;

FIG. 7 shows waveforms of signals of the circuit shown in FIG. 6;

FIG. 8 is a circuit diagram showing a gate signal generating circuit, which is another variation of the circuit shown in FIG. 4;

FIG. 9 shows waveforms of signals of the gate signal generating circuit shown in FIG. 8; and

FIG. 10 is a block diagram showing a differential signal transmitting circuit according to an embodiment of the present invention.

### DETAILED DESCRIPTION OF THE INVENTION

In the following, embodiments of the present invention will be described with reference to the drawings.

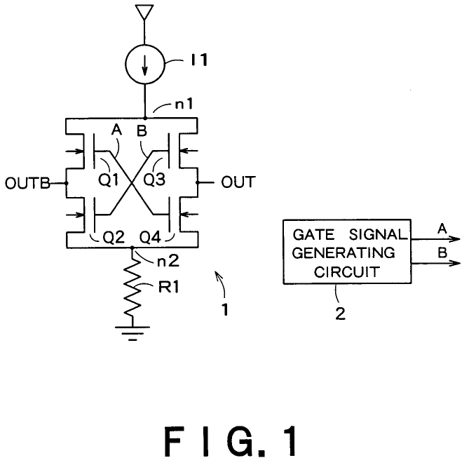

FIG. 1 is a circuit diagram showing an example of a differential signal generating circuit that generates a differential signal. The differential signal generating circuit according to this embodiment is used in a differential signal transmitting circuit, such as an LVDS, as described later.

A differential signal generating circuit 1 shown in FIG. 1 has a first transistor Q1 and a second transistor Q2 that are cascade-connected between a first common connection node n1 and a second common connection node n2, and a third transistor Q3 and a fourth transistor Q4 that are cascade-connected between the first common connection node n1 and the second common connection node n2. The differential signal generating circuit 1 further has a first differential output terminal OUTB connected to a path interconnecting the first and second transistors Q1 and Q2, a second differential output terminal OUT connected to a path interconnecting the third and fourth transistors Q3 and Q4, a current source 11 connected to the first common connection node n1, and a resistor element R1 connected between the second common connection node n2 and a grounding terminal. The first to fourth transistors Q1 to Q4 are all NMOS transistors. A pair of wires (not shown) is connected to the first and second output terminals OUTB and OUT to transmit a differential signal.

A gate signal generating circuit 2, described in detail later, supplies a signal A to the gate terminals of the first transistor Q1 and the fourth transistor Q4. The gate signal generating circuit 2 supplies a signal B to the gate terminals of the second transistor Q2 and the third transistor Q3.

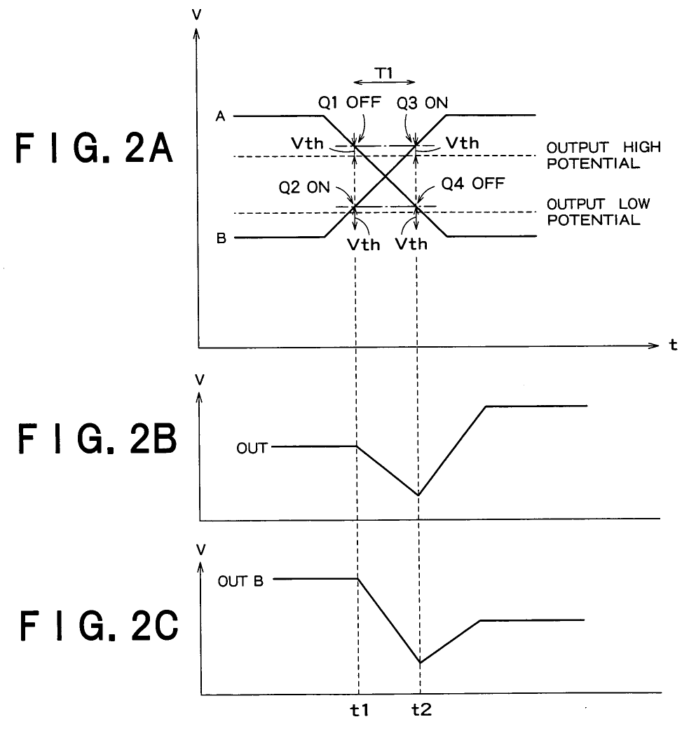

FIG. 2A is a diagram showing waveforms of the signal A and signal B according to conventional circuit, FIG. 2B is a diagram showing a waveform of the second differential output terminal OUT, FIG. 2C is a diagram showing a waveform of the first differential output terminal OUTB. As shown in FIGS. 2A and 2B, the signals A and B are signals with inverse logics according to the conventional circuit. For example, when the signal A goes high, the first and fourth transistors Q1 and Q4 are turned on. At this time, the signal B goes low, and the second and third transistors Q2 and Q3 are turned off. Therefore, one signal OUT of the differential signal becomes “Low”, and the other signal OUTB of the differential signal becomes “high”. On the other hand, when the signal A goes low, the signal B goes high, the first and fourth transistors Q1 and Q4 are turned off, and the second and third transistors Q2 and Q3 are turned on. Therefore, the signal OUT becomes “High”, and the other the signal OUTB becomes “Low”.

The signals A and B are signals with inverse logics. Typically, the logic of one of the signals is inverted to generate the other signal. In this case, however, the timings of the signals A and B differ by a delay time corresponding to one inverter. According to the conventional technique, gate signal generating circuit cancels the delay.

An NMOS transistor is turned on when the gate voltage is higher than the source voltage by a threshold voltage Vₜₕ of the transistor. As shown in FIG. 1, the source voltages of the first and third transistors Q1 and Q3 are higher than the source voltages of the second and fourth transistors Q2 and Q4. Thus, although the gate terminals of the first and fourth transistors Q1 and Q4 are connected, the two transistors are not simultaneously turned on or off. Similarly, although the gate terminals of the second and third transistors Q2 and Q3 are connected, the two transistors are not simultaneously turned on or off.

Since the source voltages of the first and third transistors Q1 and Q3 are higher than the source voltages of the second and fourth transistors Q2 and Q4, the first and third transistors Q1 and Q3 are ready to turn off and hard to turned on. On the other hand, the second and fourth transistors Q2 and Q4 are ready to turn on and hard to turned off. Therefore, the first and third transistors Q1 and Q3 remain “OFF” for several periods, and the second and fourth transistors Q2 and Q4 tend to remain “ON” for several periods.

In the differential signal generating circuit 1 shown in FIG. 1, it is assumed that at an initial stage, the first and fourth transistors Q1 and Q4 are in ON state, and the second and third transistors Q2 and Q3 are in OFF state. At this time, the differential output terminal OUTB connected to the source of the first transistor Q1 is at higher voltage, and the differential output terminal OUT connected to the drain of the fourth transistor Q4 is at lower voltage. The source voltage of the fourth transistor Q4 is lower than the drain voltage thereof by a voltage drop due to an ON resistance of the MOS transistor.

As shown in FIG. 2, when the voltage of the signal “A” falls below the voltage that higher than OUTB by Vₜₕ, the first transistor Q1 is turned off. At this time, the fourth transistor Q4 is not turned off, because the source voltage thereof is lower than the output signal voltage.

The voltage of the signal “B” gradually increases in counter to “A”. However, the source of the second transistor Q2 is connected to the second common connection node n2, and the voltage thereof is lower than the output signal voltage. Therefore, the second transistor Q2 is turned on when the voltage of the signal “B” becomes higher than that of the second common connection node n2 by the threshold voltage Vₜₕ. At this time, the third transistor Q3 is not yet turned on. At this time, the first and third transistors Q1 and Q3 are turned off, and the second and fourth transistors Q2 and Q4 are turned on.

As the voltage of the signal “A” further decreases, and the voltage of the signal “B” further increases, the third transistor Q3 is finally turned on, and the fourth transistor Q4 is finally turned off. However, even if the signals “A” and “B” are ideal ones, it takes a “T1” period from the time when Q1 turned off until the time when the third transistor Q3 is turned on.

During the period T1, since both the first and third transistors Q1 and Q3 are in OFF state, the differential output terminals OUT and OUTB are isolated from the current source I1. Essentially, the LVDS can reduce electromagnetic emission by passing the same amount of current through two signal lines in opposite directions. However, if the differential output terminals OUT and OUTB are isolated from the current source I1, the characteristic of the LVDS that the same amount of current flow in opposite directions through a pair of wires connected to the terminals is not assured.

Furthermore, if the second and fourth transistors Q2 and Q4 are turned on, charges accumulated in parasitic capacitances of the wires are discharged from the second common connection node n2 through a resistor element R1, so that currents flow from the wires to the ground terminal through the circuit shown in FIG. 1, and at the same time, the voltages of the wires decrease. In this state, the current supply path from the current source I1 is blocked as described above, so that the voltages at the differential output terminals OUT and OUTB continue to decrease (time period t1-t2 in FIGS. 2B and 2C).

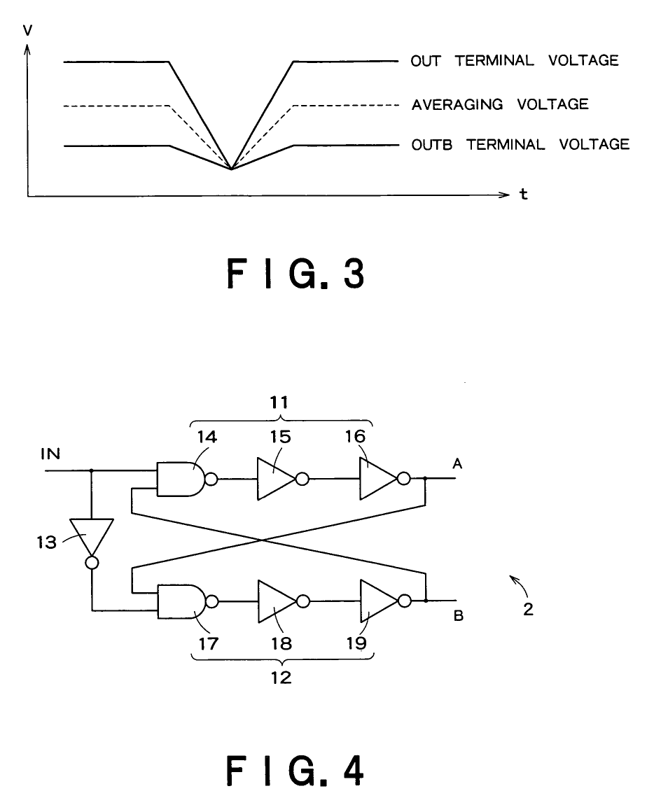

FIG. 3 shows voltages of the differential output terminals OUT and OUTB when the signals A and B switch the logics thereof. As shown FIG. 3, the current source I1 is cut off from the terminals around the time when the signals A and B switch the logics thereof, and no current flows from the pair wires into the circuit shown in FIG. 1, so that the voltages at the differential output terminals OUT and OUTB temporarily decrease significantly. As shown in FIG. 3, the voltages recover from such a decrease state to the original state when the third transistor Q3 is turned on. However, the instability of the voltage of the signal lines causes an electromagnetic noise emission.

Since there is provided no element that imposes a lower limit on the voltage of the differential output terminals OUT and OUTB, as the period T1 during which both the transistors Q1 and Q3 are in OFF state becomes longer, the voltage drop becomes more serious.

FIG. 4 is a circuit diagram showing a gate signal generating circuit 2 according to this embodiment. The circuit has a first gate signal generating section 11 that generates a signal A, a second gate signal generating section 12 that generates a signal B, and an inverter 13 that inverts an input signal IN.

The first gate signal generating section 11 has an NAND gate 14 that performs the NAND operation of the input signal IN and the output signal from the second gate signal generating section 12, inverters 15 and 16 function as buffers. The inverter 16 also output the signal A.

The second gate signal generating section 12 has an NAND gate 17 that performs the NAND operation of the output signal from the inverter 13 and the output signal from the first gate signal generating section 11, inverters 18 and 19 function as buffers. The inverter 19 also output the signal B.

As shown in FIG. 4, each of the first and second gate signal generating sections 11 and 12 uses the other output signal as an input signal to determine the logics of the signals A and B. In addition, the first and second gate signal generating sections 11 and 12 are controlled in such a manner that one of the signals A and B falls, after the other rises Therefore, the rising edge of the signals A and B has a faster timing than the falling edge. That is, the rising edge is faster than the falling edge.

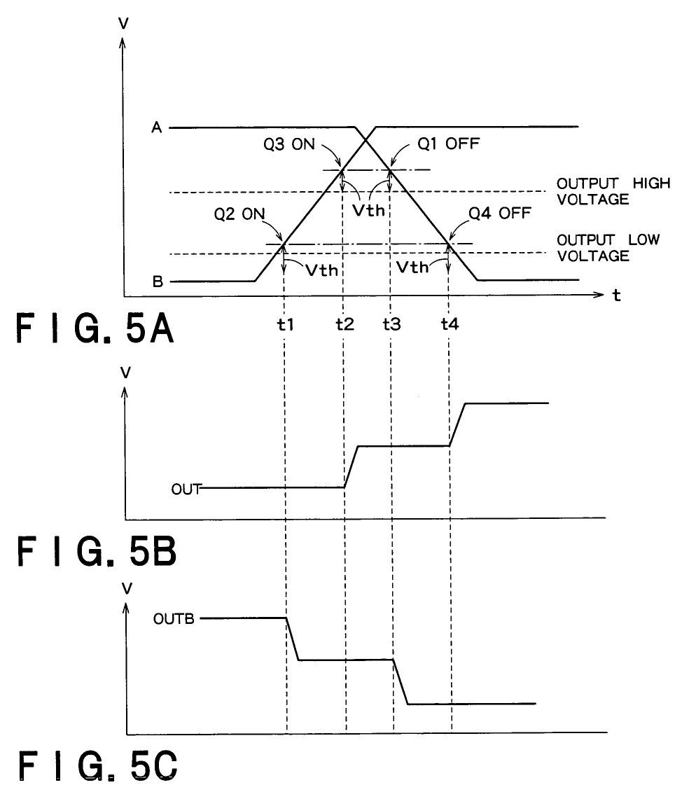

FIG. 5A is a diagram showing waveforms of the signals A and B generated by the circuit shown in FIG. 4, FIG. 5B is a diagram showing a waveform of the second differential output terminal OUT, and FIG. 5C is a diagram showing a waveform of the first differential output terminal OUTB. FIG. 5A shows also ON/OFF timings of the first to fourth transistors Q1 to Q4. In the following, an operation of the circuit shown in FIG. 4 will be described with reference to FIGS. 5A-5C.

It is supposed that the signal A is high, and the signal B is low in the initial state. As the voltage of the signal B gradually increases and reaches the voltage higher than second common connection node n2 by the threshold voltage Vₜₕ of the NMOS transistor, the second transistor Q2 is turned on (at t1). At this time, the voltage at the output terminal OUT is higher than that of the signal B, and therefore, the third transistor Q3 remains OFF state.

Then, when the voltage of the signal B becomes higher than voltage at the output terminal OUT by the threshold voltage Vₜₕ, the third transistor Q3 is turned on (at t2).

On the other hand, the signal A starts to decrease at a slightly after than the signal B. Then, at the time when the voltage of the signal A becomes lower than the voltage which the output terminal OUTB pluses the threshold voltage Vₜₕ, the first transistor Q1 is turned off (at t3).

During the period from t1 to t3, both the first and second transistors Q1 and Q2 are in ON state, there is a path through which a current flows from the current source I1 to the resistor element R1 via the first and second transistors Q1 and Q2. Therefore, voltages appear at the output terminals OUT and OUTB, respectively. That is, the output terminals OUT, OUTB are not cut from current source I1. Accordingly, there is no likelihood that the voltages at the wires are unilaterally changed to the ground side.

Then, when the voltage of the signal A becomes lower than the voltage adding the threshold voltage Vₜₕ to the voltage at the second common connection node n2, the fourth transistor Q4 is turned off (at t4).

During the period from t2 to t4, the third and fourth transistors Q3 and Q4 are in ON state, there is a current path, through which a current flows from the current source I1 to the resistor element R1 via the third and fourth transistors Q3 and Q4. Therefore, a voltage appears at the output terminals OUT and OUTB (period t2-t3 in FIGS. 5B and 5C). That is, the output terminals OUT, OUTB are not cut from current source I1. Accordingly, there is no likelihood that the voltage of wires is unilaterally changed to the ground side.

As described above, with the circuit shown in FIG. 4, the signal wires are not isolated from the current source I1 when the differential signals OUT and OUTB switch the logics thereof. Therefore, the voltage drop on the wires shown in FIG. 3 can be suppressed.

When the signals A and B switch the logics thereof, currents flow through the first and second transistors Q1 and Q2 and currents flow through the third and fourth transistors Q3 and Q4. However, the currents are limited by the current source I1 and do not cause an increase of power consumption.

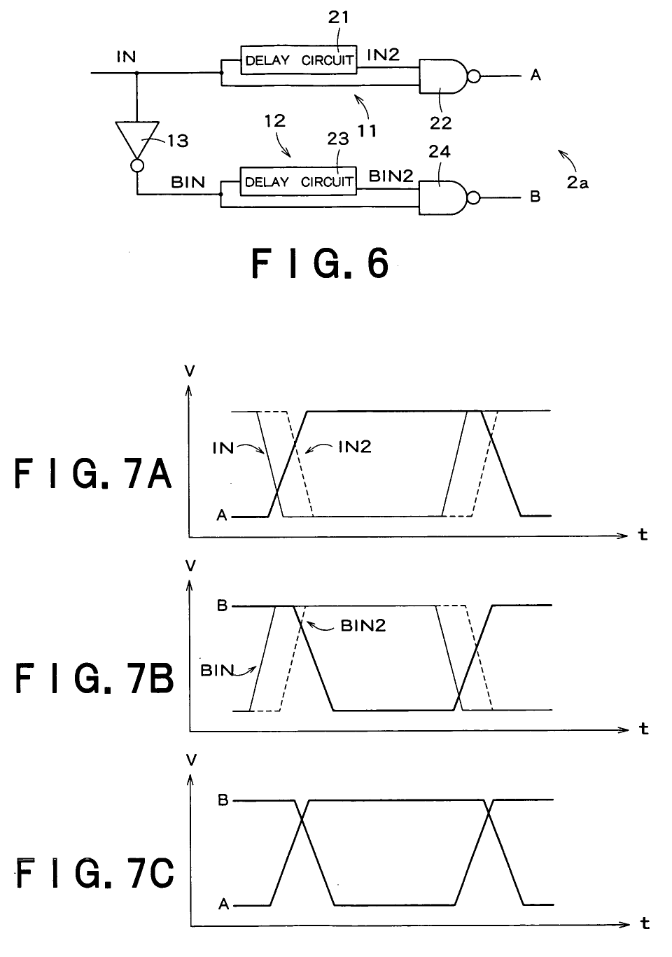

FIG. 6 is a circuit diagram showing a gate signal generating circuit 2a, which is a modification of the circuit shown in FIG. 4. The gate signal generating circuit 2a shown in FIG. 6 differs from the circuit shown in FIG. 4 in internal arrangement of first and second gate signal generating sections 11 and 12. The first gate signal generating section 11 has a delay circuit 21 that delays the input signal IN by a predetermined length of time, and an NAND gate 22 that performs the NAND operation of the input signal IN and the output signal from the delay circuit 21. The second gate signal generating section 12 has a delay circuit 23 that delays a signal BIN, inverting the input signal IN by an inverter 13, by a predetermined length of time, and an NAND gate 24 that performs the NAND operation of the signal BIN and the output signal from the delay circuit 23.

FIGS. 7A-7C shows waveforms of signals of the circuit shown in FIG. 6. FIG. 7A shows waveforms of signals of the first gate signal generating section 11, FIG. 7B shows waveforms of signals of the second gate signal generating section 12, and FIG. 7C shows waveforms of the signals A and B. As shown in FIGS. 7A-7C, the rising edge of the signals A and B has faster timing than the falling edge.

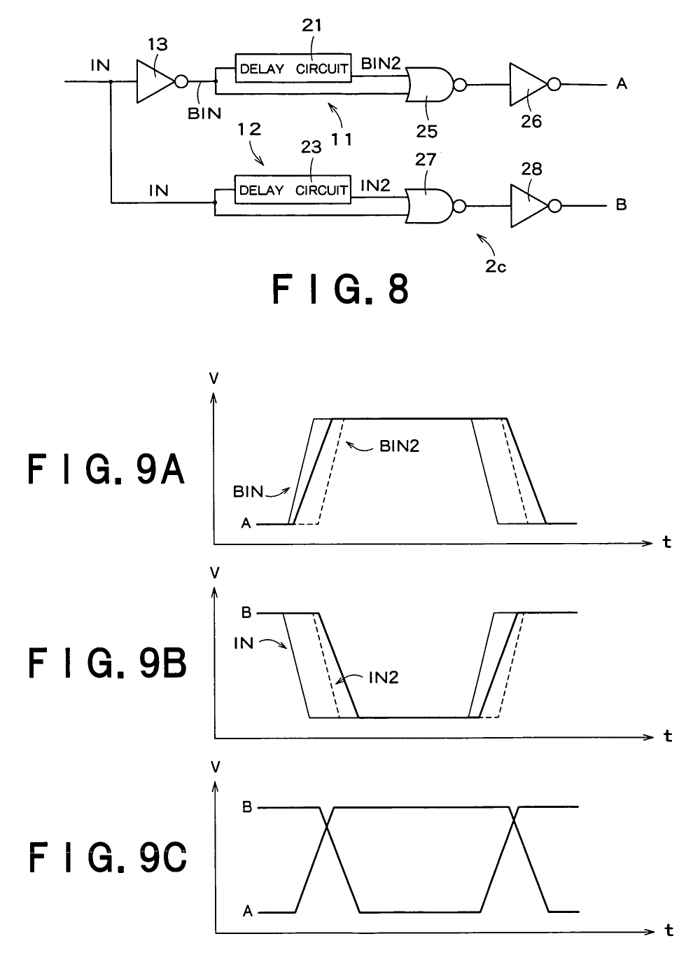

FIG. 8 is a circuit diagram showing a gate signal generating circuit 2c, which is another modification of the circuit shown in FIG. 4. The gate signal generating circuit 2c shown in FIG. 8 uses a NOR circuit instead of the NAND gates.

A first gate signal generating section 11 has a NOR gate 25 that performs the NOR operation of an inversion signal BIN produced by inverting the input signal IN and a signal produced by delaying the inversion signal BIN with a delay circuit 21 and an inverter 26 that inverts the output of the NOR gate 25. A second gate signal generating section 12 has a NOR gate 27 that performs the NOR operation of the input signal IN and a signal produced by delaying the input signal IN with a delay circuit 23 and an inverter 28 that inverts the output of the NOR gate 27.

FIGS. 9A-9C show waveforms of signals of the gate signal generating circuit 2c shown in FIG. 8. FIG. 9A shows waveforms of signals of the first gate signal generating section 11, FIG. 9B shows waveforms of signals of the second gate signal generating section 12, and FIG. 9C shows waveforms of the signals A and B. As shown in these drawings, the rising edge of the signals A and B has a faster timing than the falling edge.

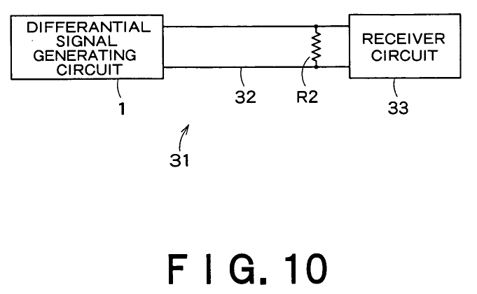

The differential signal generating circuit 1 according to this embodiment can be used as a part of a differential signal transmitting circuit based on the LVDS or the like. FIG. 10 is a block diagram showing a differential signal transmitting circuit 31 according to an embodiment of the present invention. The differential signal transmitting circuit 31 shown in FIG. 10 has a differential signal generating circuit 1 having the same configuration as that of the circuit shown in FIG. 4, 6 or 8, a pair of wires 32 that are connected to differential signal output terminals OUT and OUTB of the differential signal generating circuit 1, and a resistor element R2 connected to another end of the pair wire 32. A receiver circuit 33 or the like is connected in parallel with the resistor element R2.

The differential signal transmitting circuit 31 shown in FIG. 10 can be used in various kinds of electronic apparatus that involve a digital signal processing, including a liquid crystal display device.

In this way, according to the embodiments described above, in the circuit that generates differential signals shown in FIG. 1, when switching the logics of the differential signals, first and third transistors Q1 and Q3 are hard to turn off simultaneously. Therefore, current flowing to the signal wires 32 are kept, a temporary voltage drop on the wires 32 can be reduced, and an electromagnetic emission can be suppressed.

What is claimed is:

1. A differential signal generating circuit, comprising:
first and second transistors connected in series between a first node and a second node;
third and fourth transistors connected in series between the first node and the second node;
a first differential output terminal connected to a connection path between the first transistor and the second transistor;
a second differential output terminal connected to a connection path between the third transistor and the fourth transistor; and
a gate signal generating circuit which generates a first gate signal applied to gate terminals of the first and fourth transistors and a second gate signal applied to gate terminals of the second and third transistors, a timing when a logic of the first gate signal changes being different from a timing when a logic of the second gate signal changes.

2. A differential signal generating circuit according to claim 1, wherein when logics of the first and second differential output terminals are switched, the gate signal generating circuit generates a logic of one of the first and second differential output terminals after a logic of the other is generated.

3. A differential signal generating circuit according to claim 1, wherein the first to fourth transistors are NMOS transistors; and
the gate signal generating circuit generates the falling edge of one of first and second gate signals at a timing after rising edge of the other.

4. A differential signal generating circuit according to claim 1, wherein the gate signal generating circuit includes:
an input signal setting logics of the first and second gate signals;
a first gate signal generator which generates the first gate signal based on the input signal and the second gate signal; and
a second gate signal generator which generates the second gate signal based on the input signal and the first gate signal.

5. A differential signal generating circuit according to claim 4, wherein the first gate signal generator has a first logic operation circuit which generates a logic output based on the input signal and the second gate signal; and
the second gate signal generator has a second logic operation circuit which generates a logic output based on the input signal and the second gate signal.

6. A differential signal generating circuit according to claim 1, wherein the gate signal generating circuit includes:
a first gate signal generator which generates the first gate signal based on an input signal setting logics of the first and second gate signals and a first delay signal delayed the input signal; and
a second gate signal generator which generates the second gate signal based on the input signal and a second delay signal delayed the input signal.

7. A differential signal generating circuit according to claim 6, wherein the first gate signal generator includes a first delay circuit which delays the input signal, and a first logic operation circuit which performs a logic operation between an output signal of the first delay circuit and the input signal; and
the second gate signal generator includes a second delay circuit which delays the input signal, and a second logic operation circuit which performs a logic operation between the output of the second delay circuit and the input signal.

8. A differential signal transmitting circuit, comprising;
a differential signal generating circuit which outputs differential signals from a first differential output terminal and a second differential output terminal;
a differential transmission path at one end of which the first and second differential output terminals are connected, which transmits the differential signal; and
an impedance element connected to the differential signals at the other end of the differential transmission path,
wherein the differential signal generating circuit includes:
first and second transistors connected in series between a first node and a second node;
third and fourth transistors connected in series between the first node and the second node; and
a gate signal generating circuit which generates a first gate signal applied to gate terminals of the first and fourth transistors and a second gate signal applied to gate terminals of the second and third transistors, a timing when a logic of the first gate signal changes being different from a timing when a logic of the second gate signal changes,
said first differential output terminal being connected to a connection path of the first and second transistors; and
said second differential output terminal being connected o a connection path of the third and fourth transistors.

9. A differential signal transmitting circuit according to claim 8, wherein when logics of the first and second differential output terminals are switched, the gate signal generating circuit generates a logic of one of the first and second differential output terminals after a logic of the other is generated.

10. A differential signal transmitting circuit according to claim 8, wherein the first to fourth transistors are NMOS transistors; and
the gate signal generating circuit generates a falling edge of one of the first and second gate signals at a timing after the rising edge of the other.

11. A differential signal transmitting circuit according to claim 8, wherein the gate signal generating circuit includes:
an input signal setting logics of the first and second gate signals;
a first gate signal generator which generates the first gate signal based on the input signal and the second gate signal; and
a second gate signal generator which generates the second gate signal based on the input signal and the first gate signal.

12. A differential signal transmitting circuit according to claim 11, wherein the first gate signal generator has a first logic operation circuit which generates a logic output based on the input signal and the second gate signal; and
the second gate signal generator has a second logic operation circuit which generates a logic output based on the input signal and the second gate signal.

13. A differential signal transmitting circuit according to claim 8, wherein the gate signal generating circuit includes:
a first gate signal generator which generates the first gate signal based on an input signal setting logics of the first and second gate signals and a first delay signal delayed the input signal; and
a second gate signal generator which generates the second gate signal based on the input signal and a second delay signal delayed the input signal.

14. A differential signal transmitting circuit according to claim 13, wherein the first gate signal generator includes a first delay circuit which delays the input signal, and a first logic operation circuit which performs a logic operation between an output signal of the first delay circuit and the input signal; and
the second gate signal generator includes a second delay circuit which delays the input signal, and a second logic operation circuit which performs a logic operation between the output of the second delay circuit and the input signal.

15. A differential signal transceiver system, comprising:
a differential signal generating circuit which outputs differential signals from first and second differential output terminals;
a differential transmission path at one end of which the first and second differential output terminals are connected to transmit the differential signal;
a receiving circuit connected at the other end of the differential transmission path, which receives the differential signals; and
an impedance element connected between the differential signals at the other end of the differential transmission path,
wherein the differential signal generating circuit includes:
first and second transistors connected in series between a first node and a second node;
third and fourth transistors connected in series between the first node and the second node; and
a gate signal generating circuit which generates a first gate signal applied to gate terminals of the first and fourth transistors and a second gate signal applied to gate terminals of the second and third transistors, a timing when a logic of the first gate signal changes being different from a timing when a logic of the second gate signal changes,
said first differential output terminal being connected to a connection path of the first and second transistors; and
said second differential output terminal being connected o a connection path of the third and fourth transistors.

16. A differential signal transceiver system according to claim 15,
wherein when logics of the first and second differential output terminals are switched, the gate signal generating circuit generates a logic of one of the first and second differential output terminals after a logic of the other is generated.

17. A differential signal transceiver system according to claim 15,
wherein the first to fourth transistors are NMOS transistors; and
the gate signal generating circuit generates the falling edge of one of first and second gate signals at a timing after rising edge of the other.

18. A differential signal transceiver system according to claim 15,
wherein the gate signal generating circuit includes:
an input signal setting logics of the first and second gate signals;
a first gate signal generator which generates the first gate signal based on the input signal and the second gate signal; and
a second gate signal generator which generates the second gate signal based on the input signal and the first gate signal.

19. A differential signal transceiver system according to claim 15,
wherein the first gate signal generator has a first logic operation circuit which generates a logic output based on the input signal and the second gate signal; and
the second gate signal generator has a second logic operation circuit which generates a logic output based on the input signal and the second gate signal.

20. A differential signal transceiver system according to claim 15,
wherein the gate signal generating circuit includes:
a first gate signal generator which generates the first gate signal based on an input signal setting logics of the first and second gate signals and a first delay signal delayed the input signal; and
a second gate signal generator which generates the second gate signal based on the input signal and a second delay signal delayed the input signal.
